(19) United States
(12) Patent Application Publication
(10) Pub. No.: US 2003/0123563 A1
(43) Pub. Date: Jul. 3, 2003

(54) Method and apparatus for turbo encoding and decoding

(76) Inventor: Guangming Lu, Irvine, CA (US)

Correspondence Address: TERRANCE A. MEADOR, GRAY CARY WARE & FREIDENRICH, LLP, 4365 EXECUTIVE DRIVE, SUITE 1100, SAN DIEGO, CA, 92121-2133, US

(21) Appl. No.: 09/903,306

(22) Filed: Jul. 11, 2001

(51) Int. Cl. H03M 13/03; H04L 5/12; H04L 23/02

(52) U.S. Cl. 375/265; 375/340; 714/786

(57) ABSTRACT

A digital processing apparatus and method for executing a turbo coding routine. The apparatus and method includes adapting a turbo coding algorithm for execution by one or more reconfigurable processing elements from an array of processing elements, and then mapping the adapted algorithm onto the array for execution. A method includes configuring a portion of an array of independently reconfigurable processing elements for performing a turbo coding routine, and executing the turbo coding routine on data blocks received at the configured portion of the array of processing elements. An apparatus includes an array of interconnected, reconfigurable processing elements, where each processing element is independently programmable with a context instruction. The apparatus further includes a context memory for storing and providing the context instruction to the processing elements, and a processor for controlling the loading of the context instruction to the processing elements, for configuring a portion the processing elements to perform the turbo coding routine.

### BACKGROUND OF THE INVENTION

The present invention generally relates to digital signal processing, and more particularly to a method and apparatus for turbo encoding and decoding.

The field of digital signal processing (DSP) is growing dramatically. Digital signal processors are a key component in many communication and computing devices, for various consumer and professional applications, such as communication of voice, video, and audio signals.

The execution of DSP involves a trade-off of performance and flexibility. At one extreme of performance, hardware-based application-specific integrated circuits (ASICs) execute a specific type of processing most rapidly. However, hardware-based processing circuits are either hard-wired or programmed for an inflexible range of functions. At the other extreme, software running on a multi-purpose or general purpose computer is easily adaptable to any type of processing, but is limited in its performance. The parallel processing capability of a general purpose processor is limited.

Devices performing DSP are increasingly smaller, more portable, and consume less energy. However, the size and power needs of a device limit the amount of processing resources that can be built into it. Thus, there is a need for a flexible processing system, i.e. one that can perform many different functions, yet which can also achieve high performance of a dedicated circuit.

One example of DSP is encoding and decoding digital data. Any data that is transmitted, whether text, voice, audio or video, is subject to attack during its transmission and processing. A flexible, high-performance system and method can perform many different types of processing on any type of data, including processing of cryptographic algorithms.

Turbo has become one of the most used and researched encoding and decoding methods, as its performance is close to the theoretical Shannon limit. Turbo codes has been adopted as a Forward Error Correct (FEC) standard in the so-called Third Generation (3G) wireless communication. Most of the development focus has been on a Very Large Scale Integration (VLSI), or hardware, implementation of Turbo Codes. However, VLSI implementation lacks flexibility in the face of multiple standards (WCMDA, CMDA2000, TD-SCDMA), different code rates (1/2, 1/3, 1/4, 1/6) and different data rates (from several kilo bits/s to 2 Mbits/s). Accordingly, different VLSI chips have to be designed toward different standards, code rates, data rates, etc. On the other hand, general-purpose processors or DSP processors cannot meet the requirements of high data rate and low power consumption for a mobile device.

### BRIEF DESCRIPTION OF THE DRAWING

FIG. 1 depicts a conventional Turbo encoder arrangement.

FIG. 2 depicts a conventional Turbo decoder arrangement.

FIG. 3 is a timing diagram of a sliding window BCJR algorithm.

FIG. 4 is a trellis diagram for a 3G Turbo Coding routine with a code rate 1/3.

FIG. 5 is a block diagram of a reconfigurable processor architecture according to the invention.

FIGS. 6A and B are schematic diagrams of an array of reconfigurable processing elements illustrating internal express lanes and interconnections of the array.

FIG. 7 illustrates a Single Instruction, Multiple Data (SIMD) mode for the array.

FIG. 8 illustrates a method for mapping a log-gamma calculation routine for execution by a portion of the array of processing elements.

FIG. 9 illustrates a method for mapping a log-alpha calculation routine for execution by a portion of the array.

FIG. 10 illustrates a method for mapping a log-beta calculation routine for execution by a portion of the array.

FIG. 11 illustrates a method for mapping an LLR calculation.

FIG. 12 illustrates a method for calculating the enumerator and denominator values of the LLR operation.

FIG. 13 is a flow chart illustrating a serial mapping method for executing a Turbo coding routine, according to an embodiment of the invention.

FIG. 14 illustrates the allocation of processing elements and other resources for Turbo coding parallel computational routines.

FIG. 15 is a flow chart illustrating a parallel mapping method for executing a Turbo coding routine, according to an embodiment of the invention.

### DETAILED DESCRIPTION OF THE PREFERRED EMBODIMENTS

A reconfigurable DSP processor provides a solution to accomplish Turbo Coding according to different standards, code rates, data rates, etc., and still offer high performance and meet low-power constraints.

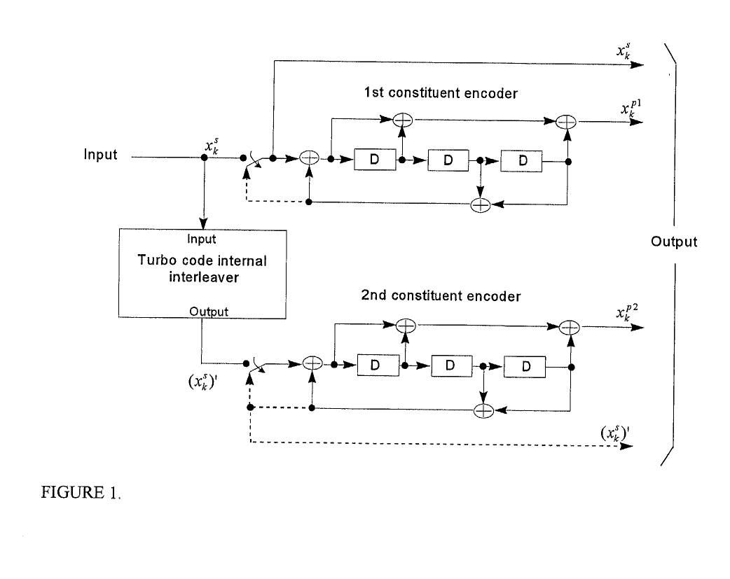

FIG. 1 is a simplified block diagram of a standard Turbo encoder. Tail bits are added during encoding. The Turbo encoder employs first and second recursive, systematic, convolutional encoders (RSC) connected in parallel, with a Turbo interleaver preceding the second RSC encoder. The outputs of the constituent encoders are punctured and repeated to achieve the different code rate as shown in Table 1. Each category of code rate is designed to support various data rates, from several kilo-bits/second to 2 Mbits/second.

TABLE 1

| | CDMA2000 | | | | | | WCDMA & TD-SCDMA |
|---|---|---|---|---|---|---|---|
| | Forward link | | | Reverse Link | | | Forward/Reverse link |
| Code rate | ½ | ⅓ | ¼ | ½ | ⅓ | ¼ | ⅓ |

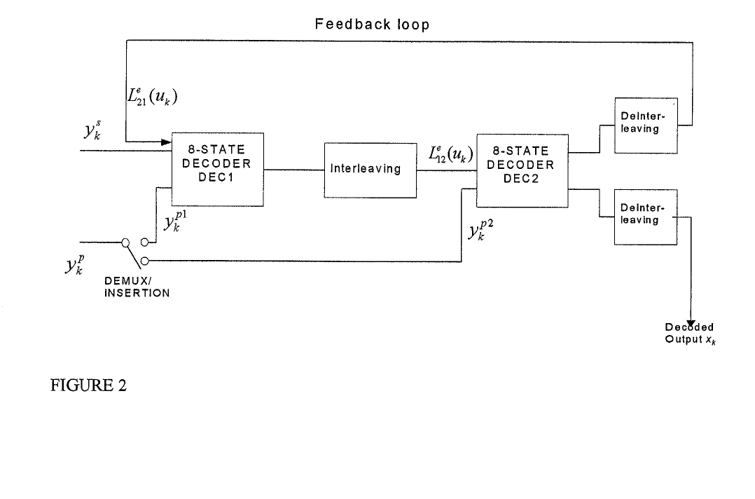

A generic Turbo decoder is shown in FIG. 2. The Turbo decoder contains two “soft” decision decoders (DEC1 and DEC2), associated with two RSC encoders, and an interleaver and de-interleaver between these two decoders as shown in FIG. 2. The decoders generate “soft” outputs, which refers to the reliability of the outputs. Basically, there are two different algorithms for generating soft outputs. The first is called symbol-by-symbol MAP (Maximum A Posteriori). The second is known as Soft Output Viterbi Algorithm (SOVA). The details of MAP and SOVA, as well as a comparison of the two algorithms, are known to those with the requisite skill in the art, but beyond the scope of this description. The MAP algorithm essentially has better performance than the SOVA algorithm at the expense of a more complicated implementation. In accordance with the invention, MAP algorithm is preferably used for executing Turbo decoding on a reconfigurable SIMD processor array. However, this invention can also accomplish Turbo decoding by mapping the SOVA algorithm to the processor array. A summary of the MAP algorithm follows.

Let m be the constituent encoder memory and S is the set of all 2^{m} constituent encoder states. Let x^{s}=(x₁^{s}, x₂^{s}. . . , x_{N}^{s})=(u₁, u₂, . . . , u_{N}) be the encoder input word or systematic information, x^{p}=(x₁^{p}, x₂^{p}. . . , x_{N}^{p}) be the parity word generated by a constituent encoder, and yₖ=(yₖ^{s}, yₖ^{p}) be a noisy (AWGN) version of (xₖ^{s},xₖ^{p}) at time instant k. y=(y₁, y₂, . . . , y_{N}) is the whole sequence of the received codewords, and yₖ=(y₁, y₂, . . . , yₖ) is the partial sequence till the time instant k.

In the symbol-by-symbol MAP decoder, the decoder decides uₖ=+1 if the conditional probability p(uₖ=+1|y) is greater than the conditional probability p(uₖ=−1|y), and it decides uₖ=−1 otherwise. More succinctly, the decision is given by the sign of L(uₖ), where L(uₖ) or Log Likelihood Ratio (LLR) is the log value of a posteriori probability (LAPP) ratio defined as:

$$L ( {u}_{k} ) {=}^{Δ} log ( \frac{p ( {u}_{k} = + 1 \vert y )}{p ( {u}_{k} = - 1 \vert y )} )$$

Incorporating the code's trellis, this may be written as:

$$L ( {u}_{k} ) {=}^{Δ} log ( \frac{{\sum }_{S +} p ( {s}_{k - 1} = {s}^{′} , {s}_{k} = s , y ) / p ( y )}{{\sum }_{S -} p ( {s}_{k - 1} = {s}^{′} , {s}_{k} = s , y ) / p ( y )} ) = log ( \frac{{\sum }_{S +} p ( {s}_{k - 1} = {s}^{′} , {s}_{k} = s , y )}{{\sum }_{S -} p ( {s}_{k - 1} = {s}^{′} , {s}_{k} = s , y )} )$$

Where sₖ ε S is the state of the encoder at time k, S+ is the set of ordered pair (s′, s) corresponding to all state transitions (sₖ₋₁=s′)→(sₖ=s) caused by data input uₖ=+1, and S− is similarly defined for uₖ=−1.

Defining αₖ₋₁(s′)=p(s′, y_{j<k}) it therefore follows:

$${γ}_{k} ( {s}^{′} , s ) = p ( s , {y}_{k} \vert {s}^{′} ) = \frac{p ( s , {s}^{′} , {y}_{k} )}{p ( {s}^{′} )} = \frac{p ( {y}_{k} \vert s , {s}^{′} ) \cdot p ( s , {s}^{′} )}{p ( {s}^{′} )} = p ( s \vert {s}^{′} ) \cdot p ( {y}_{k} \vert {s}^{′} , s ) and {β}_{k} ( s ) = p ( {y}_{j > k} \vert s )$$

It can then be shown that:

$${a}_{k} ( s ) = {\sum }_{{s}^{′} ∈ S} {a}_{k - 1} ( {s}^{′} ) {γ}_{k} ( {s}^{′} , s )$$

with initial conditions that α₀(0)=1 and α₀(s≠0)=0.

$${β}_{k - 1} ( {s}^{′} ) = {\sum }_{s ∈ S} {β}_{k} ( s ) {γ}_{k} ( {s}^{′} , s )$$

with initial conditions that β_{N}(0)=1 and β_{N}(s≠0)=0.

$${γ}_{k} ( {s}^{′} , s ) ∝ exp [ \frac{1}{2} {u}_{k} ( {L}^{e} ( {u}_{k} ) + {L}_{c} {y}_{k}^{s} ) + \frac{1}{2} {L}_{c} {x}_{k}^{p} {y}_{k}^{p} ]$$

where L^{e}(uₖ) is the extrinsic information from the previous stage and

$${L}_{c} {=}^{Δ} \frac{4 {E}_{c}}{{N}_{0}} and \frac{{E}_{c}}{{N}_{0}}$$

is the signal to noise ratio in the channel.

$$L ( {u}_{k} ) = log ( \frac{{\sum }_{S +} {α}_{k - 1} ( {s}^{′} ) \cdot {γ}_{k} ( {s}^{′} , s ) \cdot {β}_{k} ( s )}{{\sum }_{S -} {α}_{k - 1} ( {s}^{′} ) \cdot {γ}_{k} ( {s}^{′} , s ) \cdot {β}_{k} ( s )} )$$

Further, L(uₖ) (for the case of DEC1) can be rewritten as

L₁(uₖ)=L_{c}yₖ^{s}+L₂₁^{e}(uₖ)+L₁₂^{e}(uₖ)

The first term L_{c}yₖ^{s} in the above equation is the channel value, the second term represents any a priori information about uₖ provided by a previous decoder, and the third term represents extrinsic information that can be passed on to a subsequent decoder.

Now, the LOG-MAP algorithm is described. If the log domain is considered, then it follows:

\tilde{α}ₖ(s)=ln(αₖ(s))

\tilde{β}ₖ(s)=ln(βₖ(s))

\tilde{γ}ₖ(s′,s)=ln(γₖ(s′,s))

$$L ( {u}_{k} ) = log ( \frac{{\sum }_{S +} {α}_{k - 1} ( {s}^{′} ) \cdot {γ}_{k} ( {s}^{′} , s ) \cdot {β}_{k} ( s )}{{\sum }_{S -} {α}_{k - 1} ( {s}^{′} ) \cdot {γ}_{k} ( {s}^{′} , s ) \cdot {β}_{k} ( s )} ) = log ( \frac{{\sum }_{S +} {ⅇ}^{{\tilde{α}}_{k - 1} ( {s}^{′} )} \cdot {ⅇ}^{{\tilde{β}}_{k} ( {s}^{′} )} \cdot {ⅇ}^{{\tilde{γ}}_{k} ( {s}^{′} , s )}}{{\sum }_{S -} {ⅇ}^{{\tilde{α}}_{k - 1} ( {s}^{′} )} \cdot {ⅇ}^{{\tilde{β}}_{k} ( {s}^{′} )} \cdot {ⅇ}^{{\tilde{γ}}_{k} ( {s}^{′} , s )}} ) = log ( \frac{{\sum }_{S +} {ⅇ}^{{\tilde{α}}_{k - 1} ( {s}^{′} ) + {\tilde{β}}_{k} ( {s}^{′} ) + {\tilde{γ}}_{k} ( {s}^{′} , s )}}{{\sum }_{S -} {ⅇ}^{{\tilde{α}}_{k - 1} ( {s}^{′} ) + {\tilde{β}}_{k} ( {s}^{′} ) + {\tilde{γ}}_{k} ( {s}^{′} , s )}} ) = log ( {\sum }_{S +} {ⅇ}^{{\tilde{α}}_{k - 1} ( {s}^{′} ) + {\tilde{β}}_{k} ( {s}^{′} ) + {\tilde{γ}}_{k} ( {s}^{′} , s )} ) - log ( {\sum }_{S -} {ⅇ}^{{\tilde{α}}_{k - 1} ( {s}^{′} ) + {\tilde{β}}_{k} ( {s}^{′} ) + {\tilde{γ}}_{k} ( {s}^{′} , s )} )$$

Therefore, we have

$${\tilde{a}}_{k} ( s ) = ln ( {\sum }_{{s}^{′} ∈ S} {ⅇ}^{ln ( {α}_{k - 1} ( {s}^{′} ) ) + ln ( {γ}_{k} ( {s}^{′} , s ) )} ) = ln ( {\sum }_{{s}^{′} ∈ S} {ⅇ}^{{\tilde{α}}_{k - 1} ( s ) + {\tilde{γ}}_{k} ( {s}^{′} , s )} )$$

$${\tilde{β}}_{k - 1} ( s ) = ln ( {\sum }_{s ∈ S} {ⅇ}^{ln ( {β}_{k} ( s ) ) + ln ( {γ}_{k} ( {s}^{′} , s ) )} ) = ln ( {\sum }_{s ∈ S} {ⅇ}^{{\tilde{β}}_{k} ( s ) + {\tilde{γ}}_{k} ( {s}^{′} , s )} )$$

$${\tilde{γ}}_{k} ( {s}^{′} , s ) = ( \frac{1}{2} {u}_{k} ( {L}^{e} ( {u}_{k} ) + {L}_{c} {y}_{k}^{s} ) + \frac{1}{2} {L}_{c} {x}_{k}^{p} {y}_{k}^{p} )$$

This function can be solved by using the Jacobian logarithm:

ln(e^{δ}^{₁}+e^{δ}^{₂})=max(δ₁, δ₂)+ln(1+e^{-|δ}^{₂}^{-δ}^{₁}^{|})=max(δ₁,δ₂)+f_{c}(|δ₁−δ₂|)

where f_{c}(.) is a correction function. This function is called max*. Only very few values need to be stored in the lookup table.

The LOG-MAP algorithm can be simplified to a MAX-LOG-MAP algorithm by the following approximations:

ln(e^{δ}^{₁}+e^{δ}^{₂})≈max(δ₁, δ₂)

ln(e^{δ}^{₁}+. . . +e^{δ}^{ₙ})≈max(δ₁. . . , δₙ)

Then:

$${\tilde{α}}_{k} ( s ) = ln ( {\sum }_{{s}^{′} ∈ S} {ⅇ}^{ln ( {α}_{k - 1} ( {s}^{′} ) ) + ln ( {γ}_{k} ( {s}^{′} , s ) )} ) = {max}_{{s}^{′} ∈ S} \{ {\tilde{α}}_{k - 1} ( s ) + {\tilde{γ}}_{k} ( {s}^{′} , s ) \}$$

$${\tilde{β}}_{k - 1} ( {s}^{′} ) = ln ( {\sum }_{s ∈ S} {ⅇ}^{ln ( {β}_{k} ( s ) ) + ln ( {γ}_{k} ( {s}^{′} , s ) )} ) = {max}_{s ∈ S} \{ {\tilde{β}}_{k} ( s ) + {\tilde{γ}}_{k} ( {s}^{′} , s ) \}$$

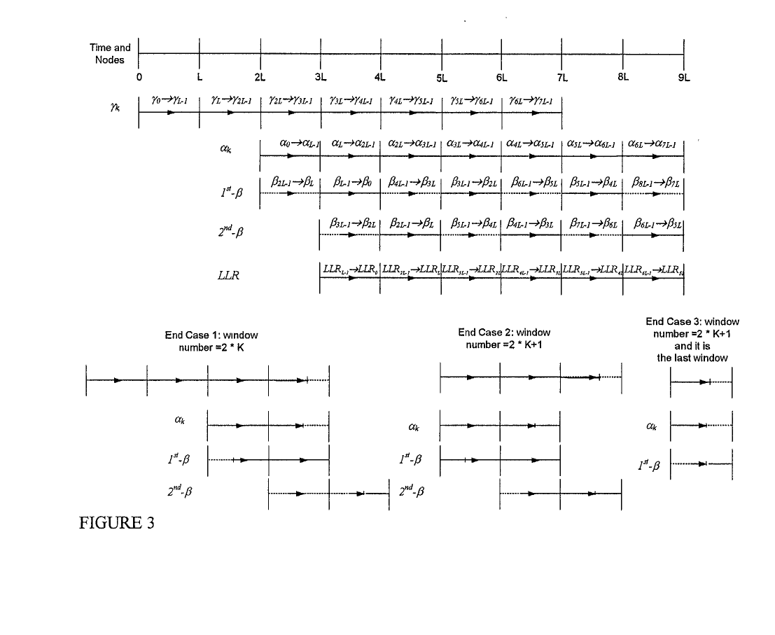

A “sliding window” is a technique used to reduce the search space, in order to reduce the complexity of the problem. A search space is first defined, called the “window.” Two sliding window approaches are SW1-BCJR and SW2-BCJR, each of which is a sliding window approach to the MAP algorithm. However the sliding window approach adopted in the MS1 Turbo decoding mapping requires only a small amount of memory independent of the block length for mapping to a reconfigurable array. FIG. 3 shows a timing diagram of a general SW-BCJR algorithm to illustrate the timing for one forward process and two synchronized backward processes with the received branch symbols.

The received branch symbols can be delayed by 2L branch times. It is sufficient if L is more than two times of the state number. Then the forward algorithm process starts at the initial node at branch time 2L, computing all state metrics for each node at every branch and storing these in a memory. The first backward process starts at the same time, but processes backward from the 2Lth node, setting every initial state metric to the same value, and not storing anything until branch time 3L, at which point it has built up reliable state metrics and encounters the last of the first set of L forward computed metrics as shown in FIG. 3. The unreliable metric branch computations are shown as dashed lines. The Lth branch soft decisions are outputs. Meanwhile, starting at time 3L, the second backward process begins processing with equal metrics at node 3L, discarding all metrics until time 4L,and so on. As shown in FIG. 3, three possible boundary cases exist for different L and block sizes.

In accordance with the invention, a new method, called MIX-LOG-MAP, is a hybrid of both Log-MAP and MAX-LOG-MAP. To compute α and β, LOG-MAP is used with a look-up table, and in LLR, the approximation approach of MAX-LOG-MAP is used. This method reduces the implementation complexity, and further can save power consumption and processing time.

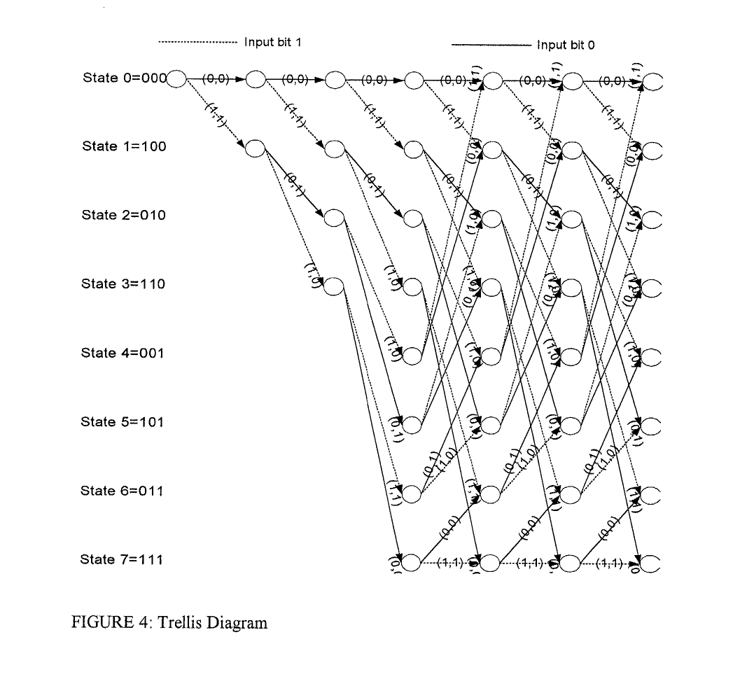

FIG. 4 shows a trellis diagram for the 3G Turbo codes with code rate 1/3. The notation for trellis branches used in the subsequent sections is (u_{b}, c_{b}). Branch start state at time (k−1) is m′, and end state at time k is m. The u_{b} is the input label; it is the input into the encoder at time k. The c_{b} is the output label, or the corresponding output of the encoder at time k.

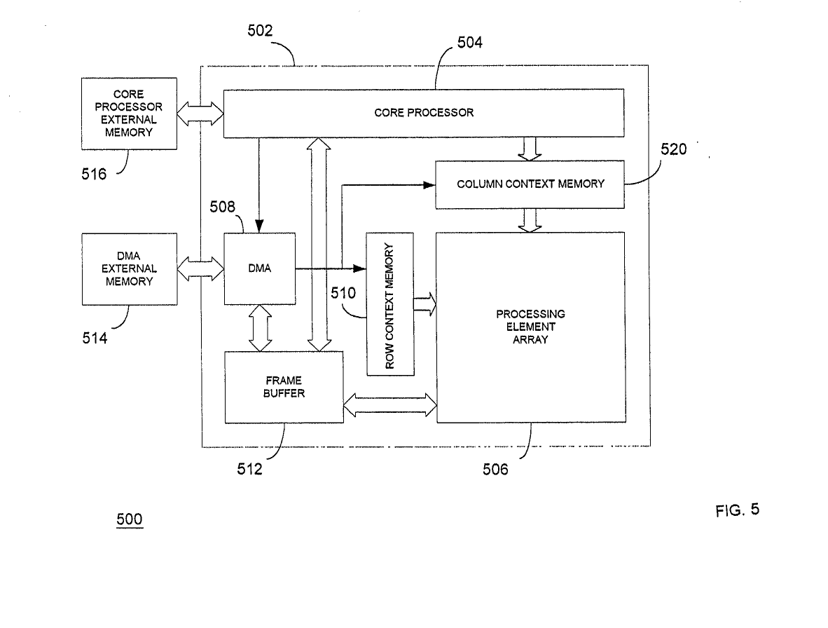

FIG. 5 shows a data processing architecture 500 in accordance with the invention. The data processing architecture 500 includes a processing engine 502 having a software programmable core processor 504 and a reconfigurable array of processing elements 506. The array of processing elements includes a multidimensional array of independently programmable processing elements, or reconfigurable cells (RCs), each of which includes functional units that can be configured for performing a specific function according to a context for the RC.

The core processor 504 is a MIPS-like RISC processor with a scalar pipeline. In one embodiment, the core processor includes sixteen 32-bit registers and three functional units: a 32-bit ALU, a 32-bit shift unit, and a memory unit. In addition to typical RISC instructions, the core processor 504 is provided with specific instructions for controlling other components of the processing engine 502. These include instructing the array of processing elements 506 and a direct memory access (DMA) controller 508 that provides data transfer between external memory 514 and 516 and the processing elements. The external memory includes a DMA external memory 514 and a core processor external memory 516.

A frame buffer 512 is provided between the DMA controller 508 and the array of processing elements 506 to facilitate the data transfer. The frame buffer 512 acts as an internal data cache for the array of processing elements 506, and includes two sets of data cache. The frame buffer 512 makes memory access transparent to the array of processing elements 506 by overlapping computation with data load and store, by alternating between the two sets of cache. Further, the input/output datapath from the frame buffer 512 allows for broadcasting of one byte of data to all of the processing elements in the array 506 simultaneously. Data transfers to and from the frame buffer 512 are also controlled by the core processor 504, and through the DMA controller 508.

The DMA controller 508 also controls the transfer of context instructions into context memory 510, 520. The context memory provides a context instruction for configuring the RC array 506 to perform a particular function, and includes a row context memory 510 and a column context memory 520 where the array of processing elements is an M-row by N-column array of RCs. Reconfiguration is done in one cycle by caching several context instructions from the external memory 514.

In a specific exemplary embodiment, the core processor is 32-bit. It communicates with the external memory 514 through a 32-bit data bus. The DMA 508 has a 32-bit external connection as well. The DMA 508 writes one 32-bit data to context memory 510, 520 each clock cycle when loading a context instruction. However, the DMA 508 can assemble the 32-bit data into 128-bit data when loading data to the frame buffer 112, or disassemble the 128-bit data into four 32-bit data when storing data to external memory 514. The data bus between the frame buffer 512 and the array of processing elements 506 is 128-bit in both directions. Therefore, each reconfigurable processing element in one column will connect to one individual 16-bit segment output of the 128-bit data bus. The column context memory 520 and row context memory 510 are each connected to the array 506 by a 256-bit (8×32) context bus in both the column and row directions. The core processor 504 communicates with the frame buffer 512 via a 32-bit data bus. At times, the DMA 108 will either service the frame buffer storing/load, row context loading or column context loading. Also, the core processor 504 provides control signals to the frame buffer 512, the DMA 108, the row/column context memories 510, 520, and array of processing elements 506. The DMA 508 provides control signals to the frame buffer 512, and the row/column context memories 510, 520.

The above specific embodiment is described for exemplary purposes only, and those having skill in the art should recognize that other configurations, datapath sizes, and layouts of the reconfigurable processing architecture are within the scope of this invention. In the case of a two-dimension array, a single one, or portion, of the processing elements are addressable for activation and configuration. Processing elements which are not activated are turned off to conserve power. In this manner, the array of reconfigurable processing elements 506 is scalable to any type of application, and efficiently conserves computing and power resources.

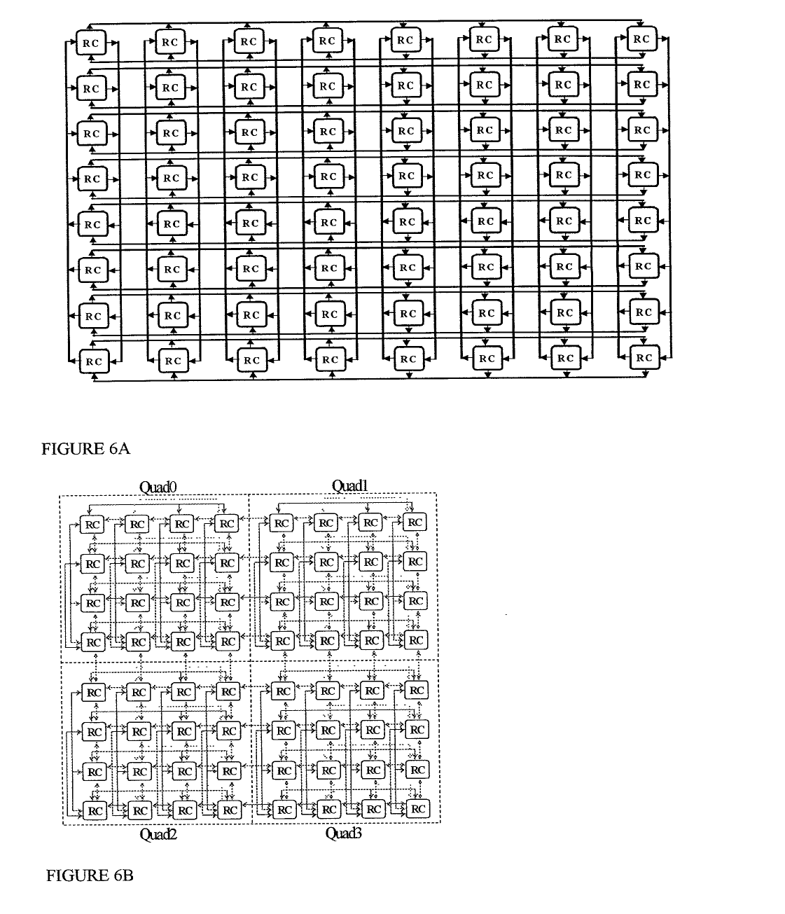

The RCs are connected in the array according to various levels of hierarchy. FIG. 6 illustrates an exemplary hierarchical configurations for an array 506 of individual RCs 507. First, RCs within each quadrant (i.e. group of 4×4 RCs) are fully connected in a row or column. Second, RCs in adjacent quadrants are connected via express lanes that enable an RC in one quadrant to broadcast its results to the RCs in an adjacent quadrant. The programmability of the interconnection network of RC array is derived from the context word. Depending upon the context, an RC can access the output of any other RC in its column or row, or select as an input from its own register file, or get the data from frame buffer. The context word provides functional programmability by configuring a logic unit of each RC to perform specific functions.

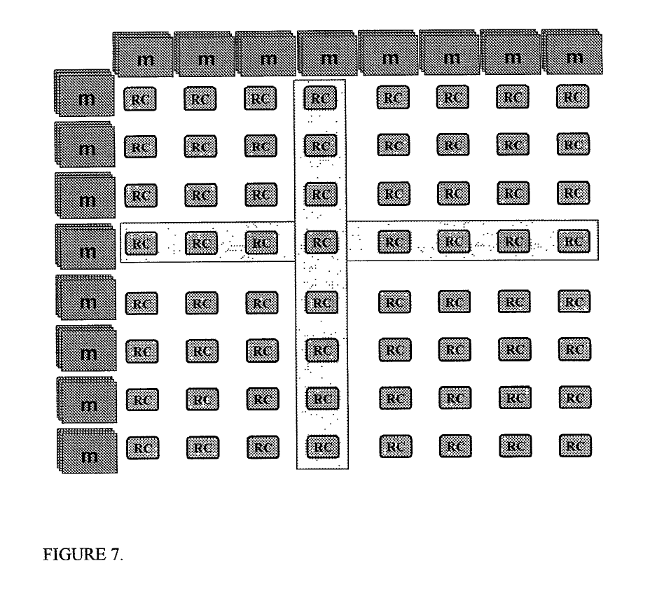

The context word from context memory is broadcast to all RCs in the corresponding row or column. Thus, all RCs in a row, and all RCs in a column share the same context word and perform the same operation, as illustrated by FIG. 7. Thus the array can operate in Single Instruction, Multiple Data form (SIMD). Alternatively, different columns or rows can perform different operations depending in different context instructions.

Executing complex algorithms with the reconfigurable architecture is based on partitioning applications into both sequential and parallel tasks. The core processor 504 executes the sequential tasks, whereas the data-parallel tasks are mapped to the RC array 506. The core processor 504 initiates all data and configuration transfers within the processing engine 502. DMA instructions initiate data transfers between the external memory 514 and the frame buffer 512, and context loading from external memory 516 into the context memories 510, 520. The RC array instructions control the operation of the RC array 506, by specifying the context and the broadcast mode.

Execution setup begins with core processor 504 requesting a configuration load from core processor external memory 516 into the respective context memory 510 and 520. Next, the core processor 504 requests the frame buffer 512 to be loaded with data from DMA external memory 514. Once the context instruction and the data are ready, the core processor 504 enables the RC array 106 execution through one of several RC array broadcast instructions. While the RC array can perform computations on data in one frame buffer set, new data may be loaded in the other frame buffer set, or the context memory may be loaded with new context instructions.

The core processor 504 controls the context broadcast mode and also provides various control/address signals for the DMA controller 508, the context memory 510 and 520, and the frame buffer 512. These control and data signals represent various components of the Turbo encoder and decoder, which are mapped to the RC array for execution. According to the invention, the mapping can occur in parallel or in serial mode, as discussed below.

According to one embodiment, a serial mapping method is used, described in reference to FIG. 2. In DEC 1 (the first decoder), the computation of the LLR (the step to compute L(uₖ)) must wait until the computations of αₖ₋₁(s′), γₖ(s′,s), βₖ(s) are done. DEC2 cannot begin to decode until the interleaver following the DEC1 is finished. In the second iteration, DEC1 cannot start until the DEC2 is completely done in the first iteration. Therefore, only one column of RCs is allocated to perform steps of αₖ₋₁(s′), βₖ(S′S), βₖ(s), and the rest of the RCs in the array will be shut down to conserve power, i.e. in a low-power mode. According to this mapping method, LOG-MAP or MAX-LOG-MAP or MIX-LOG-MAP can be employed. Thus, the serial mapping is optimal for relatively small-sized data frames.

The second approach is parallel mapping, which is based on the sliding window approach. In this case, one column and/or row of RCs are allocated to perform γ, one for α, one for 1^{st}-β, one for 2^{nd}-β and one for LLR. On top of the sliding window approach, LOG-MAP, MAX-LOG-MAP or MIX-LOG-MAP can be used. The serial mapping method is described below in greater detail.

For serial mapping (i.e. Time-Multiplexing Mapping), the procedures are determined as follows, for executing the Log-Gamma calculation:

for (k=0;k<FRAME_LENGTH;k++)
{
g00[k] = (−Lu[k]− Le[k]− Lc[k])/2;
g01[k] = (−Lu[k]− Le[k]+ Lc[k])/2;
g10[k] = (Lu[k] + Le[k]− Lc[k])/2;
g11[k] = (Lu[k] + Le[k]+ Lc[k])/2;
};

Where, Lu[k] is the systematic information, Lc[k] is parity check information and Le[k] is the a priori information. Because g00[k]=−g11[k] and g01[k]=−g10[k], it can be further optimized as:

for (k=0;k<FRAME_LENGTH;k++)
{
g10[k] = (Lu[k] + Le[k]− Lc[k])/2;
g11[k] = (Lu[k] + Le[k]+ Lc[k])/2;
};

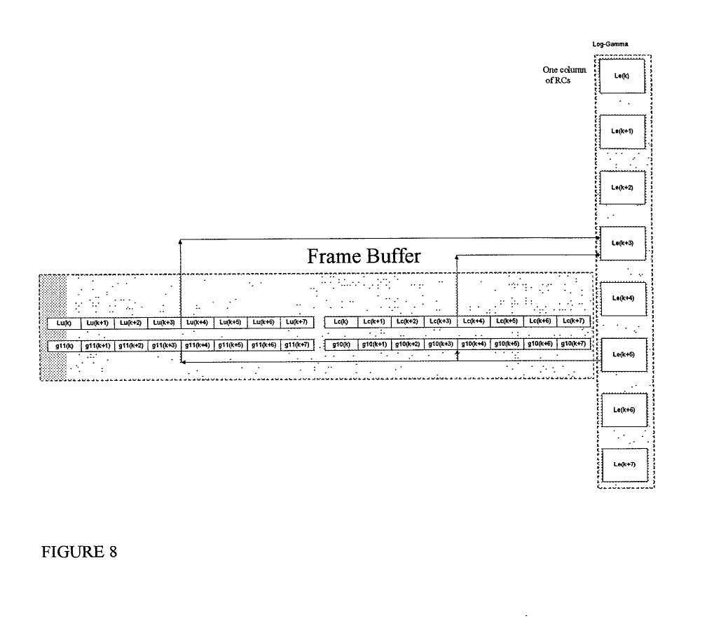

FIG. 8 illustrates a method for calculating the Log-Gamma according to an embodiment of the invention. The steps of a method are as follows:

Le(k) to Le(k+7) are loaded to one column of RC from Frame Buffer: 1 cycle

Lu(k) to Lu(k+7) are loaded to one column of RC from Frame Buffer: 1 cycle

Lc(k) to Lc(k+7) are loaded to one column of RC from Frame Buffer: 1 cycle

Perform g10(k) to g10(k+7): 1 cycle

Perform g11(k) to g11(k+7): 1 cycle

Store g10(k) to g10(k+7): 1 cycle

Store g11(k) to g11(k+7): 1 cycle

Loop index overhead: 2 cycles

The total cycles needed to perform the LOG-MAP/MAX-LOG-MAP are 9 cycles for 8 trellis stages. For the operation of Log-Gamma, only the first column of RCs is enabled for serial mapping. Table 2 summarizes the cycles and trellis stages for the Log-Gamma calculation method:

TABLE 2

| | LOG-MAP | MAX-LOG-MAP |
|---|---|---|
| MS1 | 9 cycles/8 trellis stages | 9 cycles/8 trellis stages |
| TI TMS320C62X | — | 5 cycles/2 trellis stages |
| | | (without a-priori information) |

For the Log-Alpha operation, the procedures for the MAX-LOG-MAP implementation are:

for (k=1; k<=FRAME_LENGTH;k++)
{
m_t = alpha[(k−1)*8+0] − g11[k−1];
m_b = alpha[(k−1)*8+4] + g11[k−1];
alpha[k*8+0] = (m_t > m_b) ? m_t : m_b;
m_t = alpha[(k−1)*8+0] + g11[k−1];
m_b = alpha[(k−1)*8+4] − g11[k−1];
alpha[k*8+1] = (m_t > m_b) ? m_t : m_b;
m_t = alpha [(k−1)*8+1) − g10[k−1];
m_b = alpha[(k−1)*8+5] + g10[k−1];
alpha[k*8+2] = (m_t > m_b) ? m_t : m_b;
m_t = alpha[(k−1)*8+1] + g10[k−1];
m_b = alpha[(k−1)*8+5] − g10[k−1];
alpha[k*8+3] = (m_t > m_b) ? m_t : m_b;
m_t = alpha[(k−1)*8+2] + g10[k−1];
m_b = alpha[(k−1)*8+6] − g10[k−1];
alpha[k*8+4] = (m_t > m_b) ? m_t : m_b;
m_t = alpha[(k−1)*8+2] − g10[k−1];
m_b = alpha[(k−1)*8+6] + g10[k−1];
alpha[k*8+5] = (m_t > m_b) ? m_t : m_b;
m_t = alpha[(k−1)*8+3] + g11[k−1];
m_b = alpha[(k−1)*8+7] − g11[k−1];
alpha[k*8+6] = (m_t > m_b) ? m_t : m_b;
m_t = alpha[(k−1)*8+3] − g11[k−1];
m_b = alpha[(k−1)*8+7] + g11[k−1];
alpha[k*8+7] = (m_t > m_b) ? m_t : m_b;
}

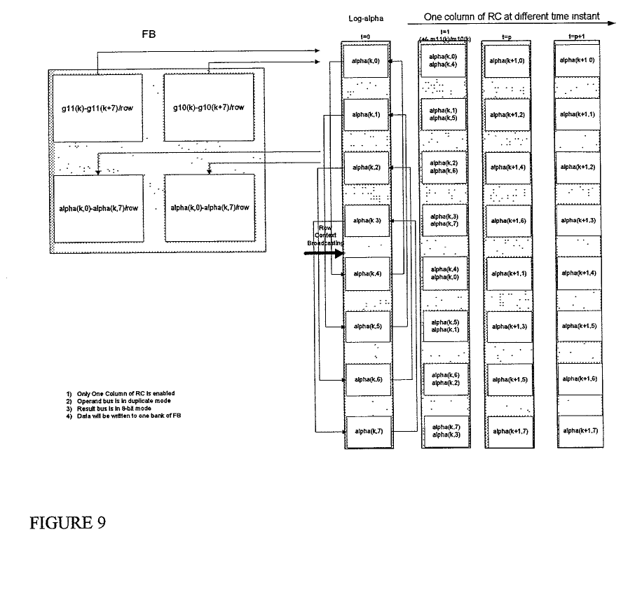

FIG. 9 is a graphical illustration of the Log-Alpha mapping method. Assume: alpha(k,0), alpha(k,1), alpha(k,2), alpha(k,3), alpha(k,4), alpha(k,5), alpha(k,6), alpha(k,7) are already in the RCs of one column of the RC array. Those data are generated in the calculation of the previous trellis stage. The context is broadcast in a row direction, and only one column, or row, of RCs is activated. The steps for executing the Log-Alpha mapping are:

RC exchanges data in 4 pairs of RCs as shown in at t=0: 1 cycle

Read 1 pair of g11(k) and g10(k). This pair data will be broadcast so that all of the RCs in one column will have the same pair of g11(k) and g10(k). Performs +/− g11(k) or +/− g10(k) based on different location: 2 cycles

Perform max* or max operation dependent on the selected algorithm in each RC, where A and B are generated in the previous step.

1) |A−B|: 1 cycle (only for LOG-MAP)

2) Max(A, B) or Lookup table of fᵣ|A−B| with Max(A,B): 1 cycle

3) max(A, B)+fᵣ|A−B|: 1 cycle (only for LOG-MAP)

Re-shuffle (using two express lanes) the data in the correct order as shown in at t=p+1: 1 cycle

Normalization max, get the max of max: 3 cycles

Propagate max of max to every RC, substrate max of max: 1 cycles

Store alpha(k+1, 0) to alpha(k+1, 7) to the frame buffer: 1 cycle

Loop index overhead: 2 cycles

Table 3 summarizes the steps and trellis stages for the Log-Alpha operation:

TABLE 3

| | LOG-MAP | MAX-LOG-MAP |
|---|---|---|
| MS1 | 14 cycles/trellis stage | 12 cycles/trellis stage |
| TI TMS320C62X | — | 9 cycles/trellis stages |
| | | (no normalization) |

The Log-Beta procedures are shown as follows:

for (k= FRAME_LENGTH − 1;k>=0;k−−){
m_t = beta[(k+1)*8 + 0] − g11[k];
m_b = beta[(k+1)*8 + 1] + g11[k];
beta[k*8 + 0] = (m_t > m_b) ? m_t : m_b;
m_t = beta[(k+1)*8 + 2] − g10[k];
m_b = beta[(k+1)*8 + 3] + g10[k];
beta[k*8 + 1] = (m_t > m_b) ? m_t : m_b;
m_t = beta[(k+1)*8 + 4] + g10[k];
m_b = beta[(k+1)*8 + 5] − g10[k];
beta[k*8 + 2] = (m_t > m_b) ? m_t : m_b;
m_t = beta[(k+1)*8 + 6] + g11[k];
m_b = beta[(k+1)*8 + 7] − g11[k];
beta[k*8 + 3] = (m_t > m_b) ? m_t : m_b;
m_t = beta[(k+1)*8 + 0] + g11[k];
m_b = beta[(k+1)*8 + 1] − g11[k];
beta[k*8 + 4] = (m_t > m_b) ? m_t : m_b;
m_t = beta[(k+1)*8 + 2] + g10[k];
m_b = beta[(k+1)*8 + 3] − g10[k];
beta[k*8 + 5] = (m_t > m_b) ? m_t : m_b;
m_t = beta[(k+1)*8 + 4] − g10[k];
m_b = beta[(k+1)*8 + 5] + g10[k];
beta[k*8 + 6] = (m_t > m_b) ? m_t : m_b;
m_t = beta[(k+1)*8 + 6] − g11[k];
m_b = beta[(k+1)*8 + 7] + g11[k];
beta[k*8 + 7] = (m_t > m_b) ? m_t : m_b;}

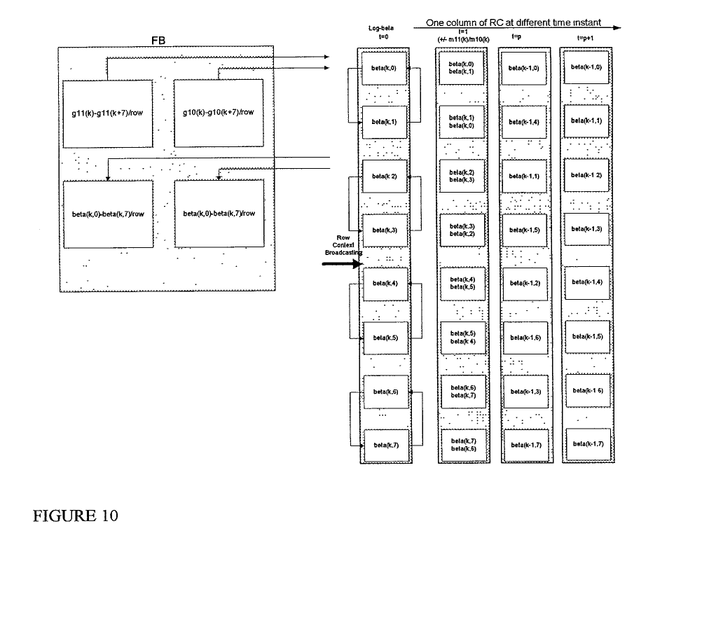

Assume: beta(k,0), beta(k,1), beta(k,2), beta(k,3), beta(k,4), beta(k,5), beta(k,6), beta(k,7) are already in the RCs of one column of the RC array. Those data are generated in the calculation of the previous trellis stage. The context is broadcast in a row direction and only one column of RC is activated. FIG. 10 illustrates the Log-Beta mapping operations. The steps of the Log-Beta method are:

RC exchanges data with its neighbor in 4 pairs of RCs: 1 cycle

Read 1 pair of g11(k) and g10(k). This pair data will be broadcast so that all of the RCs in one column will have the same pair of g11 (k) and g10(k). Performs +/− g11(k) or +/− g10(k) based on different location: 2 cycles

Perform max* or max operation dependent on the selected algorithm in each RC, where A and B are generated in the previous step.

4) |A−B|: 1 cycle (only for LOG-MAP)

5) Max(A, B) or Lookup table of fᵣ|A−B| with Max(A,B): 1 cycle

6) max(A, B)+fᵣ|A−B|: 1 cycle (only for LOG-MAP)

Re-shuffle (using two express lanes) the data in the correct order as shown in at t=p+1: 1 cycle

Normalization max, get the max of max: 3 cycles

Propagate max of max to every RC, substrate max of max: 1 cycles

Store beta(k+1, 0) to beta(k+1, 7) to the frame buffer: 1 cycle

Loop index overhead: 2 cycles

Table 4 summarizes the Log-Beta operation:

TABLE 4

| | LOG-MAP | MAX-LOG-MAP |
|---|---|---|
| MS1 | 14 cycles/trellis stage | 12 cycles/trellis stage |
| TI TMS320C62X | — | 9 cycles/trellis stages |
| | | (no normalization) |

The LLR procedures are shown as follows:

for (k=1;k<=FRAME_LENGTH;k++)
{
enumerator = −MAX;
denominator = −MAX;
t_d = alpha[(k−1)*8+0]+beta[k*8+0] − g11[k−1];
denominator = (denominator > t_d) ? denominator : t_d;
t_e = alpha[(k−1)*8+0]+beta[k*8+1] + g11[k−1];
enumerator = (enumerator > t_e) ? enumerator : t_e;
t_d = alpha[(k−1)*8+1]+beta[k*8+2] − g10[k−1];
denominator = (denominator > t_d) ? denominator : t_d;
t_e = alpha[(k−1)*8+1]+beta[k*8+3] + g10[k−1];
enumerator = (enumerator > t_e) ? enumerator : t_e;
t_d = alpha[(k−1)*8+2]+beta[k*8+5] − g10[k−1];
denominator = (denominator > t_d) ? denominator : t_d;
t_e = alpha[(k−1)*8+2]+beta[k*8+4] + g10[k−1];
enumerator = (enumerator > t_e) ? enumerator : t_e;
t_d = alpha[(k−1)*8+3]+beta[k*8+7] − g11[k−1];
denominator = (denominator > t_d) ? denominator : t_d;
t_e = alpha[(k−1)*8+3]+beta[k*8+6] + g11[k−1];
enumerator = (enumerator > t_e) ? enumerator : t_e;
t_d = alpha[(k−1)*8+4]+beta[k*8+1] − g11[k−1];
denominator = (denominator > t_d) ? denominator : t_d;
t_e = alpha[(k−1)*8+4]+beta[k*8+0] + g11[k−1];
enumerator = (enumerator > t_e) ? enumerator : t_e;
t_d = alpha[(k−1)*8+5]+beta[k*8+3] − g10[k−1];
denominator = (denominator > t_d) ? denominator : t_d;
t_e = alpha[(k−1)*8+5]+beta[k*8+2] + g10[k−1];
enumerator = (enumerator > t_e) ? enumerator : t_e;
t_d = alpha[(k−1)*8+6]+beta[k*8+4] − g10[k−1];
denominator = (denominator > t_d) ? denominator : t_d;
t_e = alpha[(k−1)*8+6]+beta[k*8+5] + g10[k−1];
enumerator = (enumerator > t_e) ? enumerator : t_e;
t_d = alpha[(k−1)*8+7]+beta[k*8+6] − g11 [k−1];
denominator = (denominator > t_d) ? denominator : t_d;
t_e = alpha[(k−1)*8+7]+beta[k*8+7] + g11 [k−1];
enumerator = (enumerator > t_e) ? enumerator : t_e;
ext[k−1] = enumerator − denominator − Lu[k−1] − La(k−1);};

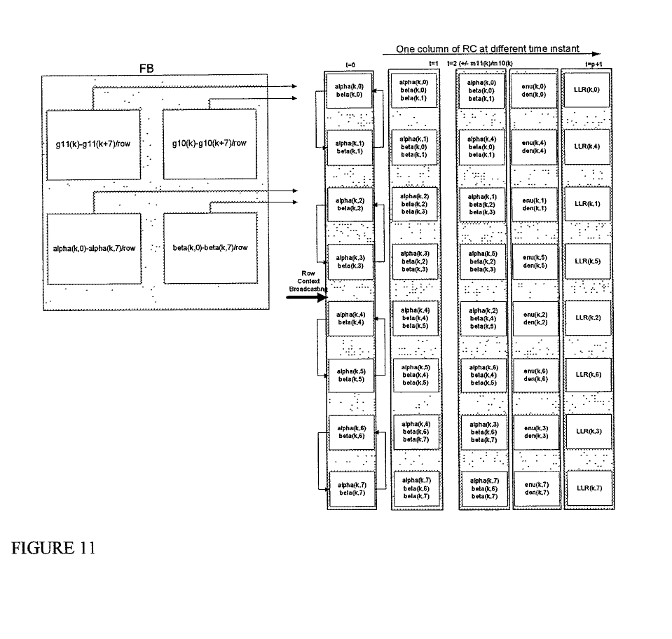

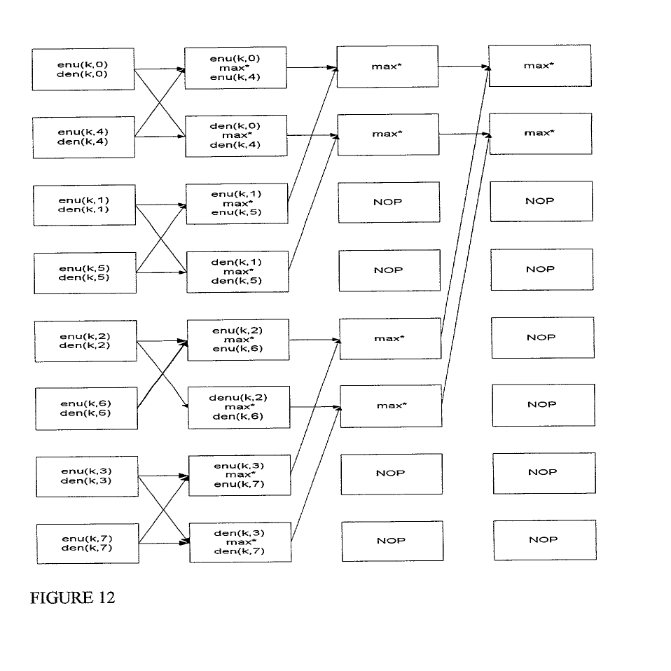

Assume: alpha(k,s), beta(k,s), g11(k)/g10(k) pair are in the frame buffer where s=0,1, . . . , 7. Those data are generated in the calculation of the Log-Gamma, Log-Alpha, Log-Beta stages. The context will be broadcast to the rows, and all of RCs are activated. FIG. 11 illustrates the LLR operations. FIG. 12 is a graphical depiction of the enumerator and denominator calculations of the LLR operations. The steps of the LLR method portion are as follows:

alpha(k,0) to alpha(k+7, 7) are loaded to each column of RC: 8×1 cycles

beta(k,0) to beta(k+7, 7) are loaded to each column of RC: 8×1 cycles

RC exchanges data in each column in 4 pairs of RCs for beta variable at t=0, the result are shown at t=1: 1 cycle

RC exchanges data in each column in 4 pairs of RCs for alpha variable. The results are shown at t=2: 1 cycle

Read 1 pair of g11(k) and g10(k). This pair data will be broadcast so that all of the RCs will have the same pair of g11(k) and g10(k). Performs alpha(k−1 ,m′) +beta(k, m) +/− g11 (k) or +/− g10(k) for enumerator and denominator based on different location: 2 cycles

Perform max* or max operation for enumerator and denominator dependent on the selected algorithm in each column. A pair of data will be performed each time, thus it will take 3 iterations to get the final max* or max. However, the Lookup operation cannot be performed in parallel because of the limitation of the Frame Buffer.

1) Max(A, B): 3×1 cycle

2) |A=B|: 3×1 cycle (only for LOG-MAP)

3) Lookup table of fᵣ|A=B|: 8×3×1 cycle (only for LOG-MAP)

4) max(A, B)+fᵣ|A−B|: 3×1 cycle (only for LOG-MAP)

Calculate the extrinsic information: enumerator-denominator-Lu(k=1): 2 cycles

Store extrinsic information to the frame buffer: 1 cycle

Loop index overhead: 2 cycles

TABLE 5
Table 5 summarizes the steps per trellis stage:

| | LOG-MAP | MAX-LOG-MAP |
|---|---|---|
| MS1 | 58 cycles/8 trellis stages | 28 cycles/8 trellis stages |
| TI TMS320C62X | — | 13 cycles/trellis stage |

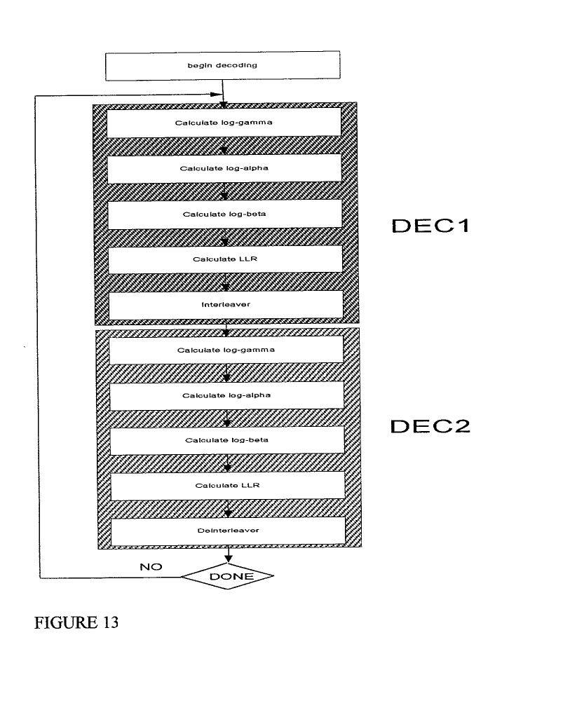

FIG. 13 shows the serial steps for the Turbo mapping method of the present invention. Its starts from the calculation of log-γ, then log-α, and finally, the LLR within one decoder (e.g. DEC1). All of the intermediate data are stored in the frame buffer. Once the LLR values are available, an interleaving/deinterleaving procedure is performed to re-order the data sequence. The above procedure is repeated for the second decoder (DEC2) in the same iteration or for the same decoder in the next iteration.

Table 6 summarizes the serial execution of a Turbo decoding method with an array of independently reconfigurable processing elements:

TABLE 6

| | | | MAX-LOG-MAP | |
|---|---|---|---|---|
| | LOG-MAP | MAX-LOG- | (TI | MIX-LOG- |
| STEPS | (MS1) | MAP (MS1) | TMS320C62X) | MAP |
| Log-Gamma | 1.13 cycles/stage | 1.13 cycles/stage | 2.5 cycles/stage | 1.13 cycles/stage |
| Log-Alpha | 14 cycles/stage | 12 cycles/stage | 9 cycles/stage | 14 cycles/stage |
| Log-Beta | 14 cycles/stage | 12 cycles/stage | 9 cycles/stage | 14 cycles/stage |
| LLR | 7.3 cycles/stage | 3.5 cycles/stage | 13 cycles/stage | 3.5 cycles/stage |
| Interleaver | 2 cycles/stage | 2 cycles/stage | ? | 2 cycles/stage |
| Total | 38.5 cycles/stage | 30.7 cycles/stage | 33.5 cycles/stage | 34.7 cycles/stage |

Table 7 summarizes the throughput, or decoded data rate, for the Turbo decoding method using the reconfigurable array, according to the invention, and using the following formula:

$$Throughput = \frac{f}{cycles \times 2 \times Iterations} \text{Mbit/s} ,$$

where f is the clock frequency (MHz) of MS 1.

TABLE 7

| LOG-MAP (MS1) | MAX-LOG MAP (MS1) | MIX-LOG-MAP |
|---|---|---|
| 0.52 Mbits/s | 0.65 Mbits/s | 0.576 Mbits/s |

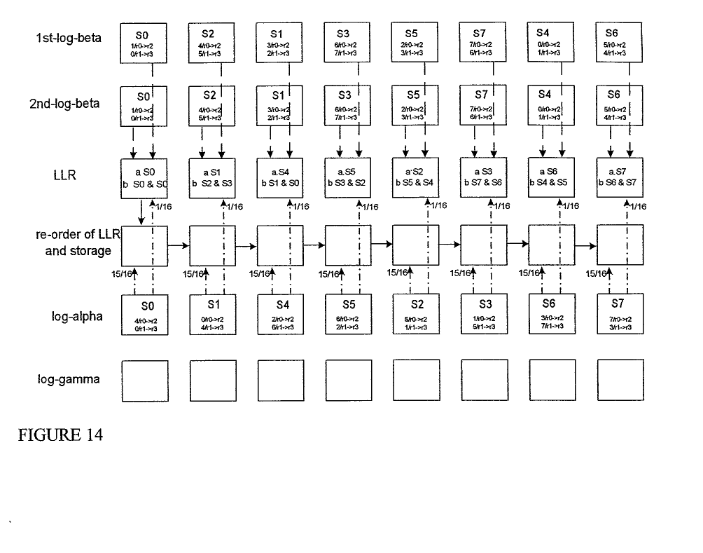

This parallel mapping is based on the MIX-LOG-MAP algorithm. The window size is twice the number of trellis states in each stage. Basically, the sliding window approach is suitable for the large frame size of CDMA2000, W-CDMA and TD-SCDMA. Parallel mapping has a higher performance, uses less memory, but has higher power consumption compared to serial mapping. The following tables show the steps for each kernel. They are the similar as the steps in the serial mapping. The resource allocation for each computational procedure in the parallel mapping is shown in FIG. 14.

Log-Gamma, using the 6^{th} row of RCs in an exemplary embodiment:

TABLE 8

| Clock cycle | Operations |
|---|---|
| 1 | Load a priori info |
| 2 | Load the systematic info Lu |
| 3 | Load the check-bit info Lc |
| 4 | Compute x = Lu + Le |
| 5 | Compute g11 = (x + Lc)/2, |
| 6 | Compute g10 = (x − Lc)/2, meanwhile, |
| | left shift by 8 to pack into H8. |
| 7 | Pack g10, g11 into 16-bit data. G10 is in H8. |
| 8 | Store the data back to Frame Buffer |

Log-Alpha, using the 5^{th} row of RCs according to an exemplary method:

TABLE 9

| Clock cycle | Operations |
|---|---|
| 1 | Configure the data bus into broadcast. |
| 2 | Load g10, g11, αₖ₋₁ + g11/g10 based on condition |
| | (condition is pre-loaded), fix the data in Feedback |
| | register/input data register. Put data in r0 |
| 3 | αₖ₋₁ − g11/g10, put data in r1 |
| 4 | Full connection, column-wise, exclusive, get r0 into r2, |
| | r0 is from other RC based on trellis diagram |
| 5 | Full connection, column-wise, exclusive, get r1 into r3, |
| | r1 is from other RC |
| 6 | Max(r2, r3) |
| 7 | \|r2 − r3\| |
| 8 | Nop (something like branch delay slot, |
| | probably can be used later) |
| 9 | LUT(fr\|A − B\|), other column RCs still can work on normal |
| | computation, max + fr(\|A − B\|) |
| 10 | Normalization max*(exclusive, row-context) |
| 11 | Normalization max*(exclusive, row-context) |
| 12 | Normalization max*(exclusive, row-context) |
| 13 | -max(exclusive, row-context) |

Log-Beta(1^{st}-Beta and 2^{nd}-Beta, using 1^{st} and 2^{d nd} row of RCs).

| Clock cycle | Operations |
|---|---|
| 1 | Load g10, g11, βₖ₊₁ + g11/g10 based on condition |
| | (condition is pre-loaded), fix the data in Feedback |
| | register/input data register. Put data in r0 |
| 2 | βₖ₊₁ − g11/g10, put data in r1 |
| 3 | Full connection, column-wise, exclusive, get r0 into r2, |
| | r0 is from other RC based on trellis diagram |
| 4 | Full connection, column-wise, exclusive, get r1 into r3, |
| | r1 is from other RC |
| 5 | Max(r2, r3) |
| 6 | \|r2 − r3\| |
| 7 | Nop (something like branch delay slot, |
| | probably can be used later) |
| 8 | LUT(fr\|A − B\|), other column RCs still can work on normal |
| | computation, max+fr(\|A − B\|) |
| 9 | Normalization max*(exclusive, row-context) |
| 10 | Normalization max*(exclusive, row-context) |
| 11 | Normalization max*(exclusive, row-context) |
| 12 | -max(exclusive, row-context) |

LLR, using the 3^{rd} row of RCs:

TABLE 10

| Clock cycle | Operations |
|---|---|
| 1 | Copy log-alpha αₖ₋₁ from storage column (6^{th} column) |
| 2 | Copy βₖ from 1^{st}-β or 2^{nd}-β, meanwhile βₖ + αₖ₋₁→rₑ |
| 3 | Full connection, column-wise, exclusive, reshuffle βₖ, |
| | meanwhile βₖ (reordered) + αₖ₋₁→r_{d} |
| 4 | -Lu(x) for every RC, frame buffer data bus in |
| | broadcast mode |
| 5 | -Le for every RC, frame buffer data bus in broadcast mode |
| 6 | Normalization max*(exclusive, row-context) |
| 7 | Normalization max*(exclusive, row-context) |
| 8 | Normalization max*(exclusive, row-context) |
| 9 | Put the data in the correct position in LLR column |
| | (exclusive, row-context) |

Table 11 illustrates a cycle schedule for all of the kernels summarized in Tables 8-10. The cycle schedule is exemplary only, based on the following criteria which may or may not necessarily be met in other embodiments:

1) no two rows of RCs access the frame buffer simultaneously.

2) if one row of RC performs a MIMD operation, the other rows will be in idle mode. In the table, “full” means a MIMD operation, others rows are in idle mode.

3) the only case that two MIMD operations can be performed in parallel is the 1st-β and 2nd-β, where the operations are the same.

TABLE 11

| | | | | Storage & | | |
|---|---|---|---|---|---|---|
| clock | 1^{st}-β | 2^{nd}-β | LLR | reorder | α | γ |
| 1 | | | | | | Le(FB) |
| 2 | | | | | | Lu(FB) |
| 3 | | | | | | Lc(FB) |
| 4 | | | | | | Le + Lu |
| 5 | | | | | | (x + Lc)/2 |
| 6 | | | | | | (x − Lc)/2 |
| 7 | | | | | | Pack |
| 8 | | | | | | Store |
| | | | | | | FB |
| 9 | | | Copy αₖ₋₁, | Copy α | FB + g10/g11 | |
| 10 | FB + g10/g11 | | FB + g10/g11 | Copy LLR | −g10/g11 | |
| 11 | −g10/g11 | FB + g10/g11 | −g10/g11 | Get Left | | |
| 12 | | −g10/g11 | Copy βₖ | | | |
| 13 | | | | | Full, for r0 | |
| 14 | | | | | Full, for r1 | |
| 15 | Full, for r0 | Full, for r0 | | | | |
| 16 | Full, for r1 | Full, for r1 | | | | |
| 17 | \|r2 − r3\| | \|r2 − r3\| | −Le | | \|r2 − r3\| | |
| 18 | Max(r2, r3) | Max(r2, r3) | βₖ + αₖ₋₁ | | Max(r2, r3) | |
| 19 | | | Full, | | | |
| | | | βₖ(2), | | | |
| 20 | NOP | NOP | βₖ(2) + αₖ₋₁ | | LUT + max | |
| 21 | LUT + max | NOP | | | | |
| 22 | | LUT + max | | | | |
| 23 | normalization 1 | normalization 1 | Max 1 | | normalization 1 | |
| 24 | normalization 2 | normalization 2 | Max 2 | | normalization 2 | |
| 25 | normalization 3 | normalization 3 | Max 3 | | normalization 3 | |
| 26 | −max | −max | | | −max | |

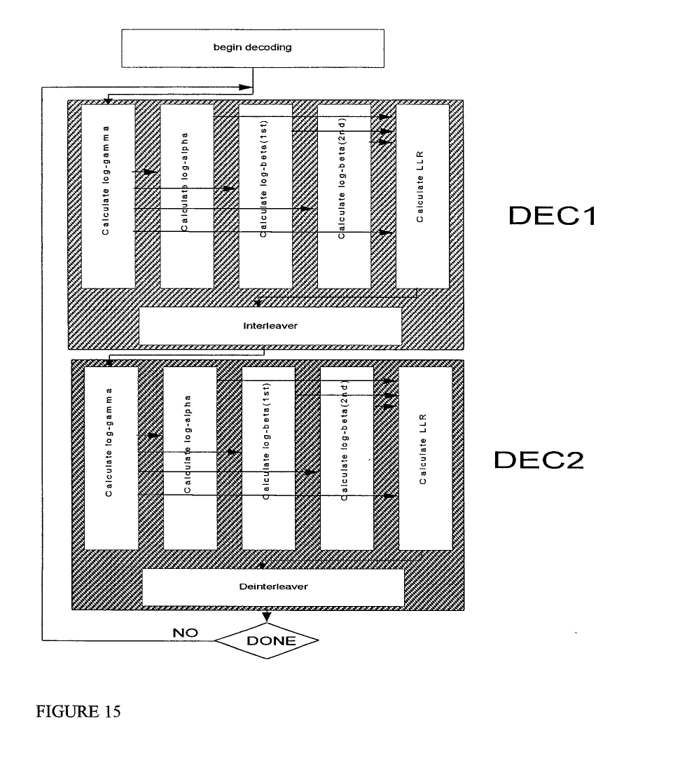

For the Log-gamma, it will be perform once every 16 group of symbols. T_{Log-gamma}=(2(data bus reconfiguration)+8×2)/16(stages)=18/16=1.125 cycles. Cycles for the rest of the operations=18.125. Thus, T_{sub-total}=1.125+18.125=19.25 cycles. If the clock cycles for the interleaver are 2*L_{frame}, where L_{frame} is the frame size, and the overhead to update the loop index is 2 clock cycles, then the total number of cycles per stage will be 23.5. FIG. 15 is a flow chart illustrating the parallel mapping method of performing Turbo coding with a reconfigurable processor array.

Other arrangements, configurations and methods for executing a block cipher routine should be readily apparent to a person of ordinary skill in the art. Other embodiments, combinations and modifications of this invention will occur readily to those of ordinary skill in the art in view of these teachings. Therefore, this invention is to be limited only be the following claims, which include all such embodiments and modifications when viewed in conjunction with the above specification and accompanying drawings.

What is claimed is:

1. A digital signal processing method, comprising:
configuring a portion of an array of independently reconfigurable processing elements for performing a turbo coding routine; and
executing the turbo coding routine on data blocks received at the configured portion of the array of processing elements.

2. The method of claim 1, wherein configuring a portion of the array of reconfigurable processing elements includes activating the portion with an activation signal.

3. The method of claim 1, wherein the portion of the array of independently reconfigurable processing elements includes at least one processing element.

4. The method of claim 1, wherein executing the turbo coding routine on data blocks received at the configured portion of the array of processing elements includes encoding the data blocks.

5. The method of claim 1, wherein executing the turbo coding routine on data blocks received at the configured portion of the array of processing elements includes decoding the data blocks.

6. The method of claim 1, wherein configuring a portion of an array of independently reconfigurable processing elements for performing a turbo coding routine includes configuring the portion as a logarithmic maximum a posteriori (LOG-MAP)-based processor.

7. The method of claim 6, further comprising configuring the portion to access a look-up table.

8. The method of claim 1, further comprising idling all processing elements in the array other than the portion of processing elements configured for performing the turbo coding routine.

9. The method of claim 1, wherein each processing element includes at least one functional unit, and wherein configuring a portion of an array of independently reconfigurable processing elements for performing a turbo coding routine includes programming the functional unit to perform at least one function of the turbo coding routine.

10. The method of claim 9, wherein the function unit includes programmable logic that is configurable for performing a logical function.

11. A digital signal processing apparatus, comprising:
an array of interconnected, reconfigurable processing elements, each processing element being independently programmable with a context instruction;
a context memory connected to the array for storing and providing the context instruction to the processing elements; and
a processor connected to the array and to the context memory, for controlling the loading of the context instruction to the processing elements, for configuring a portion the processing elements to perform a turbo coding routine.

12. The apparatus of claim 11, wherein the processor is further configured to execute the turbo coding routine by controlling a state of the configured portion of processing elements.

13. The apparatus of claim 11 wherein the array, the context memory, and the processor reside on a single chip.

14. The apparatus of claim 11, wherein the turbo coding routine is an encoding process on data blocks received at the portion of the array.

15. The apparatus of claim 11, wherein the turbo coding routine is a decoding process on data blocks received at the portion of the array.

16. The apparatus of claim 11, wherein each processing element includes at least one functional unit that is programmable for performing at least one function of the turbo coding routine.

17. The apparatus of claim 16, wherein the functional unit includes programmable logic that is configurable by the context instruction.

18. The apparatus of claim 11, wherein the processor is further configured to idle all processing elements that are not of the portion of processing elements configured for performing the turbo coding routine.

19. The apparatus of claim 11, wherein the context instruction is configured to program the portion of processing elements to emulate a logarithmic maximum a posteriori (LOG-MAP) processor.

20. A digital signal processing apparatus, comprising:
a context memory for storing one or more context instructions for performing a turbo coding routine; and
an array of independently reconfigurable processing elements, each of which is responsive to a context instruction for being configured to execute a portion of the turbo coding routine.
